(19) United States
(12) Patent Application Publication
(10) Pub. No.: US 2026/0304895 A1
(43) Pub. Date: Oct. 1, 2026

(54) TRANSISTOR STRUCTURE AND METHOD OF FORMING THE SAME

(71) Applicant: Taiwan Semiconductor Manufacturing Company, Ltd., Hsinchu (TW)

(72) Inventors: Yi-Cheng Chu, Chiayi City (TW); Chien-Hua Huang, Miaoli County (TW); Shu-Hong Ou, Tainan City (TW)

(73) Assignee: Taiwan Semiconductor Manufacturing Company, Ltd., Hsinchu (TW)

(21) Appl. No.: 19/097,801

(22) Filed: Apr. 1, 2025

(51) Int. Cl. H10D 64/23; H10D 30/01; H10D 84/01; H10D 84/85

(52) U.S. Cl. CPC H10D 64/257; H10D 30/027; H10D 84/0186; H10D 84/856

(57) ABSTRACT

A transistor structure and a method of forming the same are provided. The transistor structure includes a gate electrode disposed in a dielectric layer of an interconnect structure, a high-k dielectric layer disposed on the gate electrode, a channel layer disposed on the high-k dielectric layer, an electrode disposed on and in contact with the channel layer, and a liner layer surrounding sidewalls of the electrode. The liner layer is spaced apart from the channel layer by the electrode. The liner layer has a resistivity higher than the electrode. The electrode includes a glue layer disposed on and in contact with the channel layer, and a metallic portion surrounded by the glue layer.

### BACKGROUND

Individual transistors, interconnects, and related structures have become increasingly smaller and there is an ongoing need to develop new materials, processes, and designs of semiconductor devices and interconnects to allow further progress. Thin-film transistors are an attractive option for back-end-of-line (BEOL) integration and may not damage previously fabricated front-end-of-line (FEOL) and middle end-of-line (MEOL) devices. Circuits based on thin-film transistor devices may further include other components that may be fabricated in a BEOL process, such as capacitors, inductors, resistors, and integrated passive devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an exemplary structure after formation of transistors and an interconnect structure electrically connected to the transistors in accordance with some embodiments of the present disclosure.

FIG. 2A to FIG. 2H are schematic cross-sectional views of stages in a formation method of a transistor structure in accordance with some embodiments of the present disclosure.

FIG. 3A to FIG. 3B are schematic cross-sectional views of stages in a formation method of a transistor structure in accordance with some embodiments of the present disclosure.

FIG. 4A to FIG. 4B are schematic cross-sectional views of stages in a formation method of a transistor structure in accordance with some embodiments of the present disclosure.

FIG. 5A to FIG. 5D are schematic top views of exemplary arrays after formation of electrodes of transistor structures in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A transistor structure and a method of forming the same are provided. A transistor structure has an electrode (e.g. a source/drain electrode) disposed in a dielectric layer, disposed on a channel layer, and surrounded by a liner layer. The electrode covers a bottom surface of the liner layer, covers the whole revealed surface of the channel layer exposed from the dielectric layer, and is in contact with sidewalls of the dielectric layer. The liner layer is spaced apart from the channel layer by the electrode. Accordingly, the transistor structure has a lower resistance since the current directly goes from the electrode to the channel layer without the reduction of the current (Iₒₙ) caused by the issue that the liner layer with a higher resistivity is in contact with the channel layer. Also, the stability, the performance, and the lifetime of the transistor structure are improved since the liner layer surrounding sidewalls of the electrode prevents the transistor structure from the damage of the subsequent processes. The damage may be caused by the invasion of the elements such as hydrogen atom (H) or other defect elements coming from the subsequent processes such as the silicon oxide deposition, the gas treatment, the plasma bombard or the like. The formation of the electrode and the liner layer are formed by the method including deposition/and removal processes of a sacrificial layer rather than using a plasma process such as the plasma bombard that would damage the quality of the transistor structure. Therefore, the reliability and the performance of the transistor structure are improved.

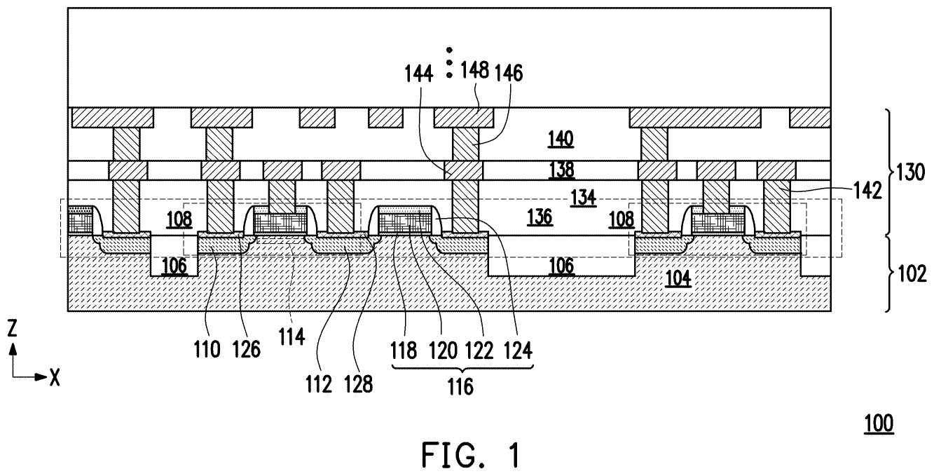

FIG. 1 is a schematic cross-sectional view of an exemplary structure after formation of transistors and an interconnect structure electrically connected to the transistors in accordance with some embodiments of the present disclosure.

Referring to FIG. 1, a semiconductor structure 100 includes a substrate 102, which may be a semiconductor substrate such as a commercially available silicon substrate. The substrate 102 includes a semiconductor material layer 104. For example, the semiconductor material layer 104 is a surface portion of a bulk semiconductor substrate, or is a top semiconductor layer of a semiconductor-on-insulator (SOI) substrate. In some embodiments, the semiconductor material layer 104 includes a single crystalline semiconductor material such as single crystalline silicon.

Shallow trench isolation (STO) structures 106 including a dielectric material such as silicon oxide is formed in an upper portion of the semiconductor material layer 104. Suitably doped semiconductor wells, such as p-type wells and n-type wells, may be formed within each area that is laterally enclosed by a portion of the shallow trench isolation structures 106. Field effect transistors 108 is formed over a top surface of the semiconductor material layer 104. Each of the field effect transistors 108 includes a source electrode 110, a drain electrode 112, a semiconductor channel 114 that includes a surface portion of the substrate 102 extending between the source electrode 110 and the drain electrode 112, and a gate structure 116. In some embodiments, the semiconductor channel 114 includes single crystalline semiconductor material such as single crystalline silicon.

Each gate structure 116 includes a gate dielectric layer 118, a gate electrode 120, a gate cap dielectric 122, and a dielectric gate spacer 124. A source-side metal-semiconductor alloy region 126 is formed on each source electrode 110, and a drain-side-metal-semiconductor alloy region 128 may be formed on each drain electrode 112. In some embodiments, the devices formed on the top surface of the semiconductor material layer 104 include complementary metal-oxide-semiconductor (CMOS) transistors and optionally additional semiconductor devices (such as resistors, diodes, capacitors, etc.) that are collectively referred to as CMOS circuitry 134. In other embodiments, the devices formed on the top surface of the semiconductor material layer 104 may include any suitable type of transistors.

In some embodiments, the field effect transistors 108 in the CMOS circuitry 134 is electrically connected to the respective thin-film transistor of an interconnect structure 130. The interconnect structure 130 includes metal wirings 142, 144, 146, 148 formed within respective dielectric layers 136, 138, 140 which are over the substrate 102, the shallow trench isolation structures 106 and the semiconductor devices (such as field effect transistors 108). The field effect transistors 108 in the CMOS circuitry 134 are electrically connected to the metal wirings 142, 144, 146, 148. In some embodiments, the interconnect structure 130 includes etch stop layers (ESLs) (not shown) formed below respective dielectric layers.

For example, the ESLs and the dielectric layers may be formed alternately, and the metal wirings 142, 144, 146, 148 formed in the ESLs and the dielectric layers. For example, each of the dielectric layers 136, 138, 140 includes a dielectric material such as undoped silicate glass, a doped silicate glass, organosilicate glass, amorphous fluorinated carbon, porous variants thereof, or combinations thereof. In some embodiments, each of the dielectric layers 136, 138, 140 includes a dielectric material such as silicon dioxide (SiO₂), silicon oxynitride (SiON), silicon oxycarbide (SiOC). In some embodiments, the dielectric layers 136, 138, 140 are formed by a deposition process such as chemical vapor deposition (CVD), or the like. For example, each of the ESLs includes a dielectric material such as aluminum oxide (AlOx), aluminum nitride (AlN), silicon oxycarbide (SiOC), silicon carbon nitride (SiCN), or the like. In some embodiments, the ESLs are formed by a deposition process such as CVD, physical vapor deposition (PVD) or atomic layer deposition (ALD). For example, each of the metal wirings 142, 144, 146, 148 includes a metallic fill material such as tungsten (W), copper (Cu), aluminium (Al), cobalt (Co), ruthenium (Ru), molybdenum (Mo), tantalum (Ta), titanium (Ti), titanium nitride (TiN), alloys thereof, and/or combinations thereof. Each of the metal wirings 142, 144, 146, 148 may include a metallic liner such as TiN, TaN, WN, TiC, TaC, and WC.

In FIG. 1, only four metal wirings 142, 144, 146, 148 and three dielectric layers 136, 138, 140 are shown on the substrate 102 for simplicity, but the disclosure is not limited thereto. More layers of the metal wirings and the dielectric layers may be formed over the substrate 102. In some embodiments, thin-film transistors are formed in a dielectric layer of the interconnect structure 130 and electrically connected to the metal wirings within the dielectric layer of the interconnect structure 130.

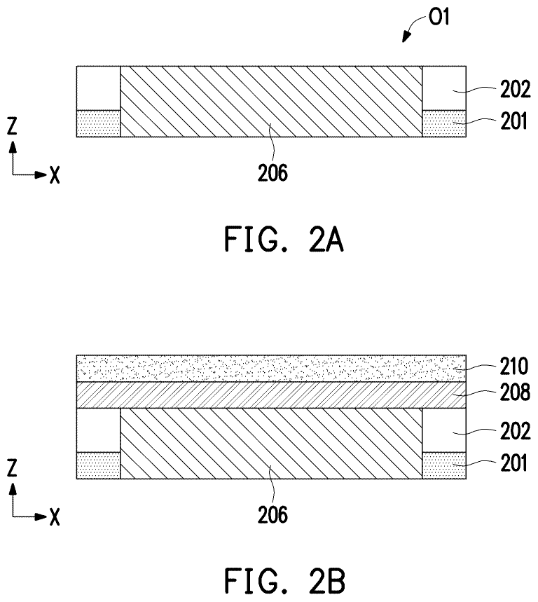

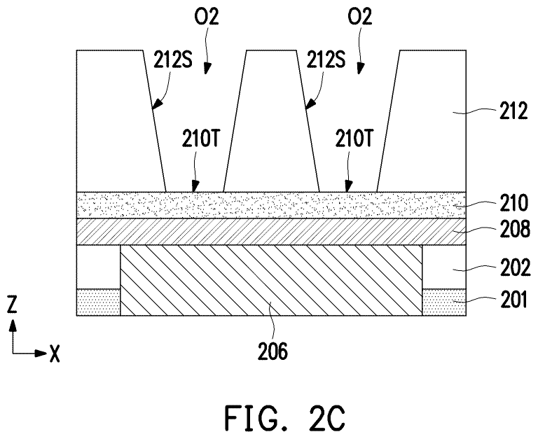

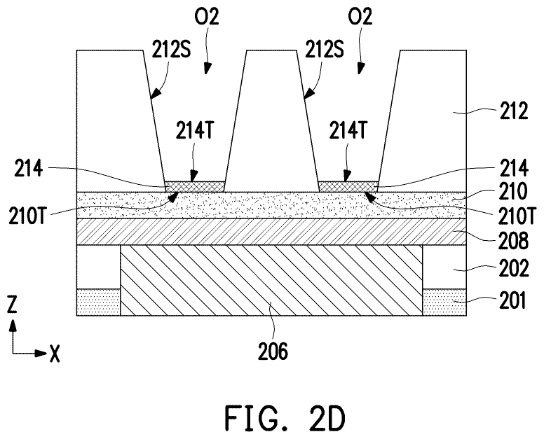

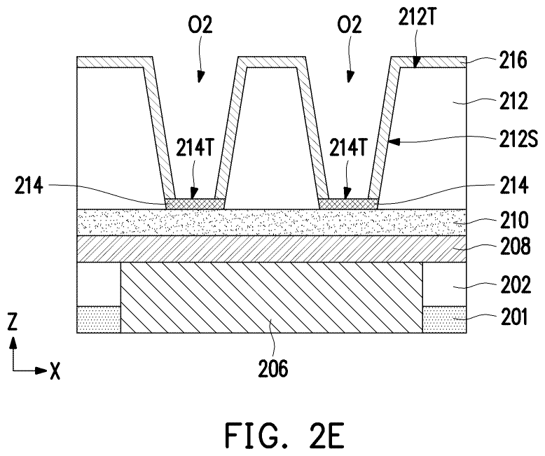

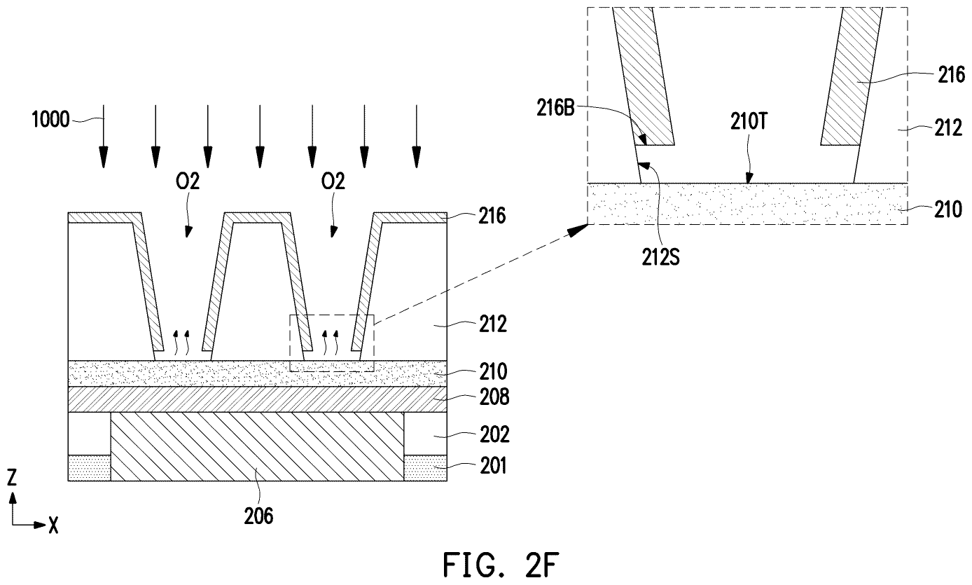

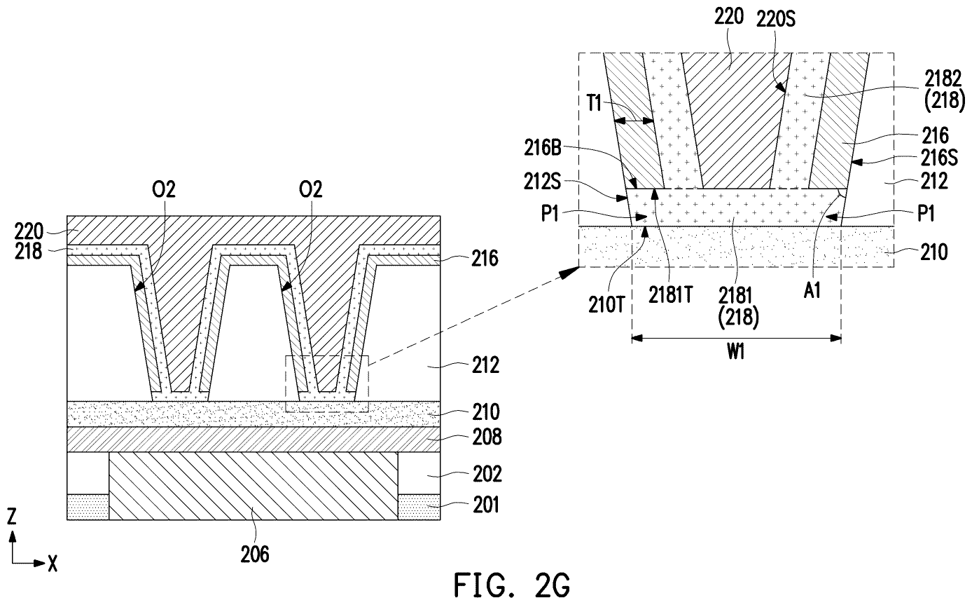

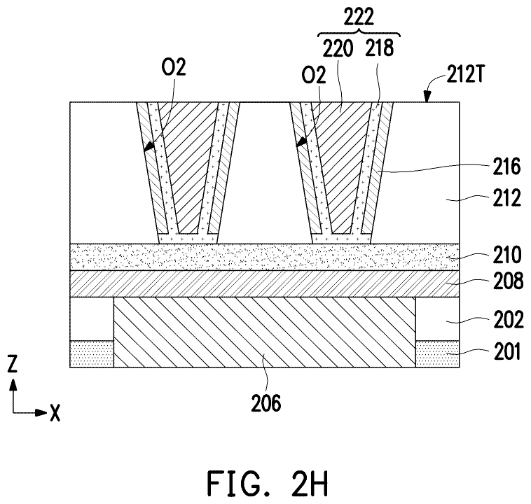

FIG. 2A to FIG. 2H are schematic cross-sectional views of stages in a formation method of a transistor structure in accordance with some embodiments of the present disclosure.

Referring to FIG. 2A, an etch stop layer (ESL) 201 and a dielectric layer 202 formed on the ESL 201 are included in the interconnect structure 130 of FIG. 1. The formation processes and the materials of the ESL 201 and the dielectric layer 202 are the same as the ESLs and the dielectric layers of the interconnect structure 130 of FIG. 1, and will not be repeated herein. A removal process or a patterning process is performed on the dielectric layer 202 and the ESL 201 to remove a portion of the dielectric layer 202 and the ESL 201, thereby an opening O1 (e.g., a cavity) is formed in the dielectric layer 202 and the ESL 201. For example, the removal process includes a dry etching process, a wet etching process, or a combination thereof. In some embodiments, a photoresist (not shown) is formed over the dielectric layer 202. The photoresist may then be patterned using photolithography techniques to generate an opening in the photoresist. The patterned photoresist may then be used as a mask for patterning the dielectric layer 202 and the ESL 201. After performing the removal process, any residual photoresist is removed by an ash process or by dissolution with a solvent.

In some embodiments, a conductive material layer 206 fills the opening O1 in the dielectric layer 202 and the ESL 201. The conductive material layer 206 not only fills the opening O1, but also covers a top surface of the dielectric layer 202 (not shown). The conductive material layer 206 may include a metallic liner material and/or a metallic fill material. For example, the metallic liner material includes a conductive metallic nitride or a conductive metallic carbide such as TiN, TiN/W, Ti/Al/Ti, TaN, WN, TiC, TaC, and/or WC. For example, the metallic fill material includes W, Cu, Al, Co, Ru, Mo, Ta, Ti, TiN, TaN, tungsten carbide nitride (WCN), alloys thereof, and/or combinations thereof. In some embodiments, each of the metallic liner material and the metallic fill material is formed by suitable deposition process such as CVD, PVD, ALD, an electroplating process, or the like.

In some embodiments, a planarization process (e.g. a chemical-mechanical planarization (CMP) process) is performed to remove excess portions of the conductive material layer 206 until the top surface of the dielectric layer 202 is revealed. Then, a gate electrode 206 is formed in the opening O1. The gate electrode 206 is embedded in the dielectric layer 202 and the ESL 201, and a top surface of the gate electrode 206 substantially levels with the top surface of the dielectric layer 202.

Referring to FIG. 2B, a high-k (high dielectric constant) dielectric layer 208 is formed on the gate electrode 206 and the dielectric layer 202, and a channel layer 210 is formed on the high-k dielectric layer 208. For example, the high-k dielectric layer 208 includes a dielectric material such as hafnium dioxide (HfO₂), zirconium dioxide (ZrO₂), aluminium oxide (Al₂O₃), titanium dioxide (TiO₂) or the like. In some embodiments, the high-k dielectric layer 208 is formed by a deposition process such as ALD, PVD, CVD or the like. In some embodiments, the high-k dielectric layer 208 may be patterned by any suitable process to form the patterned high-k dielectric layer 208 on the gate electrode 206. In other embodiments, the high-k dielectric layer 208 may not be patterned after the high-k dielectric layer 208 is formed on the gate electrode 206. For example, the channel layer 210 includes indium gallium zinc oxide (In—Ga—Zn—O, IGZO), gallium zinc tin oxide (Ga—Zn—Sn—O, GZTO), hafnium indium zinc oxide (Hf—In—Zn—O, HIZO), indium zinc oxide (In—Zn—O, IZO) or the like. In some embodiments, the channel layer 210 is formed by a deposition process such as ALD, PVD, CVD or the like. In some embodiments, the channel layer 210 is patterned by any suitable process to form the patterned channel layer 210 on the high-k dielectric layer 208.

Referring to FIG. 2C, a dielectric layer 212 is formed on the channel layer 210 and the high-k dielectric layer 208, and openings O2 (e.g. source/drain electrode openings) are formed in the dielectric layer 212. A top surface 210T of the channel layer 210 and sidewalls 212S of the dielectric layer 212 are revealed by the openings O2. The formation processes and the materials of the dielectric layer 212 are the same as the dielectric layer 202, and will not be repeated herein. A removal process or a patterning process is performed on the dielectric layer 212 to remove a portion of the dielectric layer 212, thereby the openings O2 are formed in the dielectric layer 212. For example, the removal process includes a dry etching process, a wet etching process, or a combination thereof. In some embodiments, a photoresist (not shown) is formed over the dielectric layer 212. The photoresist may then be patterned using photolithography techniques to generate openings in the photoresist. The patterned photoresist may then be used as a mask for patterning the dielectric layer 212. After performing the removal process, any residual photoresist is removed by an ash process or by dissolution with a solvent.

Referring to FIG. 2D, a sacrificial layer 214 is formed on the whole revealed top surface 210T of the channel layer 210. The sacrificial layer 214 is formed with a flat top surface 214T (referred to as a flat sacrificial layer). The flat top surface 214T of the sacrificial layer 214 is substantially parallel to the top surface 210T of the channel layer 210. For example, the top surface 214T of the sacrificial layer 214 may be hydrophobic. The sacrificial layer 214 is deposited to cover the top surface 210T of the channel layer 210 and a portion of the sidewalls 212S of the dielectric layer 212 at a bottom of the openings O2. For example, a material of the sacrificial layer 214 includes 1-chlorobenzotriazole, 5-chlorobenzotriazole, 5-methyl-1H-benzotriazole, 1-methyl-1H-1,2,3-benzotriazole-5-carbaldehyde, 1-methyl-1H-1,2,3-benzotriazol-5-amine, 1-methylimidazole, 2-mercapto-1-methylimidazole, 1-methylimidazole-2-sulfonyl chloride, 5-chloro-1-methylimidazole, 5-iodo-1-methylimidazole, thiamazole, 1-methylimidazolium chloride, 2,5-dibromo-1-methyl-1H-imidazole, 1H-benzotriazole-4-sulfonic acid, benzotriazole (BTA), or the like.

In some embodiments, the sacrificial layer 214 is formed by a selective deposition process such as ALD or the like. The sacrificial layer 214 is selectively deposited on the top surface 210T of the channel layer 210. A material of the sacrificial layer 214 grows from the top surface 210T of the channel layer 210, and the grown the sacrificial layer 214 is in contact with a portion of the sidewalls 212S of the dielectric layer 212. In some embodiments, the selective deposition process is performed, based on the inherent property (e.g. hydrophilicity or hydrophobicity) difference of the materials of the channel layer 210 and the dielectric layer 212. In other embodiments, the selective deposition process is performed based on a blocking layer (not shown) such as a self-assembled monolayer (SAM). The blocking layer is removed after the selective deposition process is performed.

Referring to FIG. 2E, a liner layer 216 is formed on the revealed sidewalls 212S and the top surface 212T of the dielectric layer 212. In some embodiments, a material of the liner layer 216 includes metal, alloy, nitride, carbide, metal oxide, or the like. The hydrogen permeability of the material of the liner layer 216 is lower than of silicon oxide (SiO₂). For example, a material of the liner layer 216 includes aluminium oxide (Al₂O₃), erbium oxide (Er₂O₃), chromium oxide (Cr₂O₃), silicon nitride (SiN), zirconium nitride (ZrN), titanium aluminium nitride (TiAlN), chromium nitride (Cr₂N), aluminium Chromium nitride (AlCrN), or the like. In some embodiments, the liner layer 216 is formed by a selective deposition process such as ALD, electroless plating or the like. The liner layer 216 is selectively deposited on the top surface 212T and the sidewalls 212S of the dielectric layer 212. The material of the liner layer 216 grows from the oxide surface (such as the top surface 212T and the sidewalls 212S) of the dielectric layer 212. Then, the grown liner layer 216 is in contact with the top surface 214T of the sacrificial layer 214.

Referring to FIG. 2F, the sacrificial layer 214 is removed to form a cavity at the bottom of the openings O2. The cavity reveals the top surface 210T of the channel layer 210, a portion of the sidewalls 212S of the dielectric layer 212, and a bottom surface 216B of the liner layer 216. In some embodiments, the sacrificial layer 214 is removed by a removal process 1000 such as a wet etching process, a thermal process, or the like. In some embodiments, the sacrificial layer 214 is removed by performing an isotropic etching process such as a wet etching process using etchants which are selective to the materials of the sacrificial layer 214, while the liner layer 216 and the channel layer 210 remain relatively un-etched as compared to the sacrificial layer 214. In some embodiments, a removed thickness of the liner layer 216 or the channel layer 210 may be less than 2 angstrom (Å). For example, the etchants may be deionized water (diH₂°), any suitable organic etchant, a combination thereof, or the like. In some embodiments, the sacrificial layer 214 is removed (e.g. thermal decomposed) by performing a thermal process (e.g. thermal decomposition process) in a process chamber (such as on the hotplate or in the oven) under a temperature from greater than about 100° C. to less than about 300° C. When the thermal process is performed, a clean gas may be applied to the process chamber. For example, the clean gas may be nitrogen (N₂) gas, argon (Ar) gas, air gas, or a combination thereof.

Referring to FIG. 2G, a glue layer 218 is formed on the top surface 210T of the channel layer 210, on the revealed sidewalls 212S of the dielectric layer 212, and on the liner layer 216. The glue layer 218 covers the channel layer 210, covers the bottom surface 216B of the liner layer 216, and is in contact with the dielectric layer 212. The glue layer 218 fills the cavity below the bottom surface 216B of the liner layer 216. The liner layer 216 is spaced apart from the channel layer 210 by the glue layer 218. The liner layer 216 is not contact with the channel layer 210. For example, a material of the glue layer 218 includes titanium (Ti), tungsten-titanium (TiW), tantalum (Ta), chromium (Cr), cobalt (Co), or the like. In some embodiments, the glue layer 218 is formed by ALD, CVD, PVD or the like. In some embodiments, a thickness of the glue layer is less than 60 angstrom (Å).

A metallic material 220 is formed on the glue layer 218 and fills the openings O2. The metallic material 220 is surrounded by the glue layer 218. For example, the metallic material 220 includes Al, Cu, Au, Pt, Ag, Ti, W, Ni, TiN. In some embodiments, the metallic material 220 is formed by suitable deposition process such as CVD, PVD, ALD, an electroplating process, or the like. The liner layer 216 has a resistivity higher than the glue layer 218 and the metallic material 220.

The glue layer 218 includes a first portion 2181 extending on the top surface 210T of the channel layer 210, and a second portion 2182 extending from the first portion 2181 and surrounding sidewalls 220S of the metallic portion 220. A protrusion P1 of the first portion 2181 of the glue layer 218 extends below the bottom surface 216B of the liner layer 216, and is in contact with the sidewalls 212S of the dielectric layer 212. The first portion 2181 of the glue layer 218 extends below the metallic portion 220. The first portion 2181 of the glue layer 218 is sandwiched between the top surface 210T of the channel layer 210 and the bottom surface 216B of the liner layer 216, and between the top surface 210T of the channel layer 210 and the metallic portion 220. The second portion 2182 of the glue layer 218 is sandwiched between the sidewalls 220S of the metallic portion 220 and sidewalls 216S of the liner layer 216.

The first portion 2181 of the glue layer 218 is formed with a flat top surface 2181T (referred to as a flat portion). The flat top surface 2181T of the first portion 2181 of the glue layer 218 is substantially parallel to the top surface 210T of the channel layer 210. In some embodiments, as illustrated in FIG. 2G, an included angle A1 between the sidewall 212S of the dielectric layer 212 and the flat top surface 2181T of the first portion 2181 of the glue layer 218 is equal to or less than about 90 degrees. A minimum width W1 of the first portion 2181 of the glue layer 218 ranges from greater than 0 to less than about 200 nm. A thickness T1 of the liner layer 216 ranges from greater than 0 to less about 0.4 times the minimum width W1 of the first portion 2181 of the glue layer 218.

Referring to FIG. 2H, a removal process (e.g., a planarization process) is performed to remove excess portions of the glue layer 218 and the metallic portion 220 until the top surface 212T of the dielectric layer 212 is revealed such that electrodes 222 (e.g. source/drain electrodes) are formed in the openings O2. The electrode 222 includes the glue layer 218 and the metallic portion 220 surrounded by the glue layer 218. The electrode 222 is embedded in the dielectric layer 212, and a top surface of the electrode 222 substantially levels with the top surface 212T of the dielectric layer 212. The above-mentioned removal process may include a chemical-mechanical planarization (CMP) process although other suitable removal processes may be used. A height of the electrode 222 ranges from about 5 nm to about 500 nm. The formation of the electrode 222 and the liner layer 216 are formed by a method including the deposition process of the sacrificial layer 214 and the removal process 1000 of the sacrificial layer 214, rather than using a plasma process to remove the liner layer 216. The plasma process such as the plasma bombard causes the damage of the quality of the transistor structure.

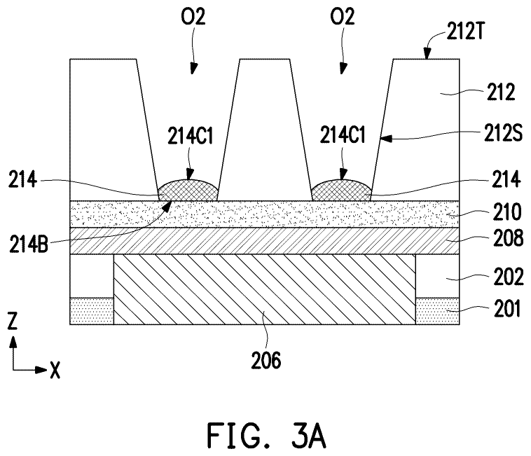

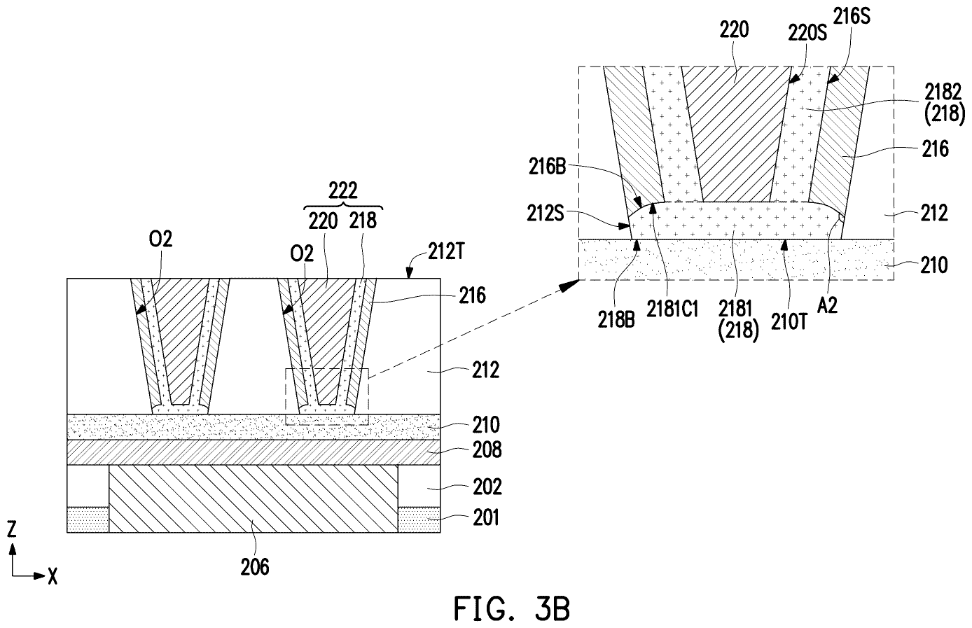

FIG. 3A to FIG. 3B are schematic cross-sectional views of stages in a formation method of a transistor structure in accordance with some embodiments of the present disclosure. Except for the further description, the definition of the reference symbols and labeled representations are the same as FIG. 2A to FIG. 2H, and will not be repeated herein.

Referring to FIG. 3A and FIG. 3B, a sacrificial layer 214 is formed on the whole revealed surface of channel layer 210. The sacrificial layer 214 is deposited to cover the channel layer 210 and a portion of the sidewalls 212S of the dielectric layer 212 at a bottom of the openings O2. The sacrificial layer 214 is formed with a convex top surface 214C1 (referred to as a convex sacrificial layer). The convex top surface 214C1 of the sacrificial layer 214 protrudes out of the sacrificial layer 214. The convex top surface 214C1 of the sacrificial layer 214 has a convex shape in a cross-sectional view (as shown in FIG. 3A), and the convex top surface 214C1 has a center portion extending towards the top surface 212T of the dielectric layer 212. The convex top surface 214C1 of the sacrificial layer 214 is opposite to a bottom surface 214B of the sacrificial layer 214 that is in contact with the channel layer 210. An edge portion of the convex top surface 214C1 is in contact with the sidewalls 212S of the dielectric layer 212. A distance of the center portion of the convex top surface 214C1 relative to a bottom surface 214B is greater than a distance of the edge portion of the convex top surface 214C1 relative to the bottom surface 214B. For example, the convex top surface 214C1 of the sacrificial layer 214 may be hydrophobic.

The liner layer 216 is formed on the revealed sidewalls 212S and the top surface 212T of the dielectric layer 212 after the sacrificial layer 214 is formed. The bottom surface 216B of the liner layer 216 is a concave surface concave into the liner layer 216. The bottom surface 216B of the liner layer 216 is in contact with the convex top surface 214C1 of the sacrificial layer 214 (not shown in FIG. 3A and FIG. 3B). The sacrificial layer 214 is removed to form a cavity at the bottom of the openings O2.

The glue layer 218 is formed to fill the cavity at the bottom of the openings O2, and the glue layer 218 is on the channel layer 210, on the revealed sidewalls 212S of the dielectric layer 212, and on the liner layer 216. In some embodiments, the glue layer 218 fills the cavity below the bottom surface 216B of the liner layer 216. The glue layer 218 covers the channel layer 210, covers the bottom surface 216B of the liner layer 216, and is in contact with the revealed dielectric layer 212. The liner layer 216 is spaced apart from the channel layer 210 by the glue layer 218. The liner layer 216 is not in contact with the channel layer 210.

The glue layer 218 includes a first portion 2181 extending on the top surface 210T of the channel layer 210, and a second portion 2182 extending from the first portion 2181 and surrounding sidewalls 220S of the metallic portion 220. The first portion 2181 of the glue layer 218 extends below the bottom surface 216B of the liner layer 216 and the metallic portion 220, and is in contact with the sidewalls 212S of the dielectric layer 212.

The first portion 2181 of the glue layer 218 has a convex top surface 2181C1 in contact with the bottom surface 216B of the liner layer 216. The bottom surface 216B of the liner layer 216 is a concave surface concave into the liner layer 216. The convex top surface 2181C1 of the glue layer 218 protrudes out of the glue layer 218. The convex top surface 2181C1 of the glue layer 218 has a convex shape in a cross-sectional view (as shown in FIG. 3B), and the convex top surface 2181C1 has a center portion extending towards the top surface 212T of the dielectric layer 212. The convex top surface 2181C1 of the glue layer 218 is opposite to a bottom surface 218B of the glue layer 218 that is in contact with the channel layer 210. An edge portion of the convex top surface 2181C1 is in contact with the sidewalls 212S of the dielectric layer 212. A distance of the center portion of the convex top surface 2181C1 relative to a bottom surface 218B is greater than a distance of the edge portion of the convex top surface 2181C1 relative to the bottom surface 218B. In some embodiments, as illustrated in FIG. 3B, an included angle A2 between the sidewall 212S of the dielectric layer 212 and the convex top surface 2181C1 of the first portion 2181 of the glue layer 218 is greater than the included angle A1 as shown in FIG. 2G. For example, the included angle A2 ranges from about 90 degrees to about 150 degrees.

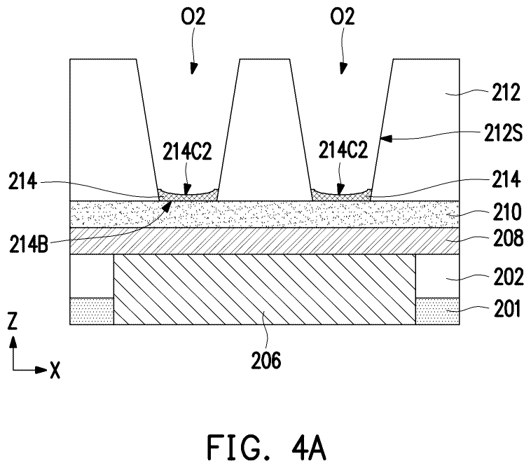

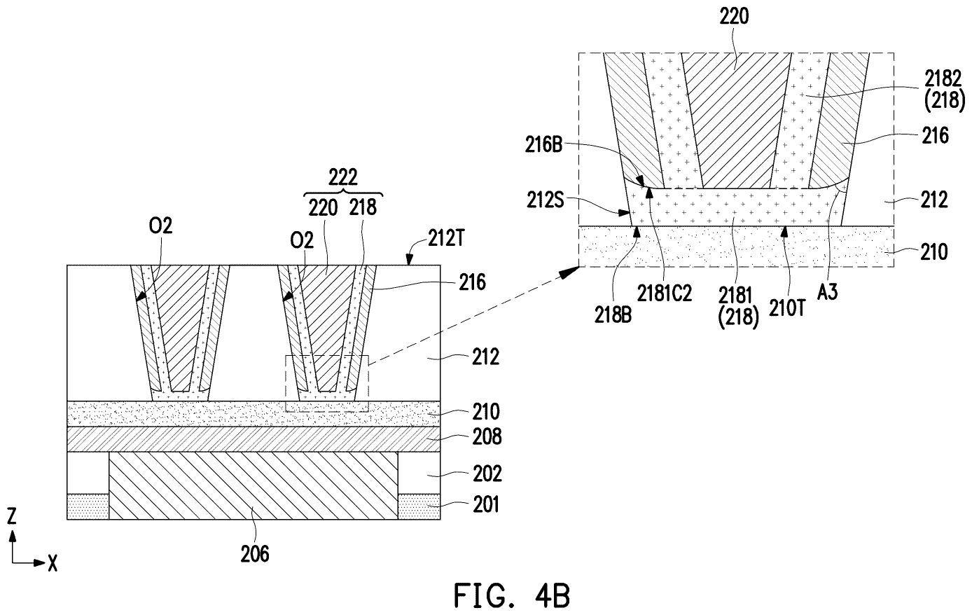

FIG. 4A to FIG. 4B are schematic cross-sectional views of stages in a formation method of a transistor structure in accordance with some embodiments of the present disclosure. Except for the further description, the definition of the reference symbols and labeled representations are the same as FIG. 2A to FIG. 2H, and will not be repeated herein.

Referring to FIG. 4A and FIG. 4B, a sacrificial layer 214 is formed on the whole revealed channel layer 210. The sacrificial layer 214 is deposited to cover the channel layer 210 and a portion of the sidewalls 212S of the dielectric layer 212 at a bottom of the openings O2. The sacrificial layer 214 is formed with a concave top surface 214C2 (referred to as a concave sacrificial layer). The concave top surface 214C2 of the sacrificial layer 214 concave into the sacrificial layer 214. The concave top surface 214C2 of the sacrificial layer 214 has a concave shape in a cross-sectional view (as shown in FIG. 4A), and the concave top surface 214C2 has a center portion concave into the bottom surface 214B of the sacrificial layer 214. The concave top surface 214C2 of the sacrificial layer 214 is opposite to the bottom surface 214B that is in contact with the channel layer 210. An edge portion of the concave top surface 214C2 is in contact with the sidewalls 212S of the dielectric layer 212. A distance of the center portion of the concave top surface 214C2 relative to the bottom surface 214B is less than a distance of the edge portion of the concave top surface 214C2 relative to the bottom surface 214B. For example, the concave top surface 214C2 of the sacrificial layer 214 may be hydrophobic.

The liner layer 216 is formed on the sidewalls 212S and the top surface 212T of the dielectric layer 212 after the sacrificial layer 214 is formed. The bottom surface 216B of the liner layer 216 is a convex surface protruding out of the liner layer 216. The bottom surface 216B of the liner layer 216 is in contact with the concave top surface 214C2 of the sacrificial layer 214 (not shown in FIG. 4A and FIG. 4B). The sacrificial layer 214 is removed to form a cavity at the bottom of the openings O2.

The glue layer 218 is formed to fill the cavity at the bottom of the openings O2, and the glue layer 218 is on the channel layer 210, on the revealed sidewalls 212S of the dielectric layer 212 and on the liner layer 216. In some embodiments, the glue layer 218 fills the cavity below the bottom surface 216B of the liner layer 216. The glue layer 218 covers the channel layer 210, covers the bottom surface 216B of the liner layer 216, and is in contact with the revealed dielectric layer 212. The liner layer 216 is spaced apart from the channel layer 210 by the glue layer 218. The liner layer 216 is not in contact with the channel layer 210.

The glue layer 218 includes a first portion 2181 extending on the top surface 210T of the channel layer 210, and a second portion 2182 extending from the first portion 2181 and surrounding sidewalls 220S of the metallic portion 220. The first portion 2181 of the glue layer 218 extends below the bottom surface 216B of the liner layer 216 and the metallic portion 220, and is in contact with the sidewalls 212S of the dielectric layer 212.

The first portion 2181 of the glue layer 218 has a concave top surface 2181C2 in contact with a bottom surface 216B of the liner layer 216. The bottom surface 216B of the liner layer 216 is a convex surface protruding out of the liner layer 216. The concave top surface 2181C2 of the glue layer 218 is concave into the glue layer 218. The concave top surface 2181C2 of the glue layer 218 has a concave shape in a cross-sectional view (as shown in FIG. 4B), and the concave top surface 2181C2 has a center portion concave into a bottom surface 218B of the glue layer 218. The concave top surface 2181C2 of the glue layer 218 is opposite to a bottom surface 218B that is in contact with the channel layer 210. An edge portion of the concave top surface 2181C2 is in contact with the sidewalls 212S of the dielectric layer 212. A distance of the center portion of the concave top surface 2181C2 relative to a bottom surface 218B is less than a distance of the edge portion of the concave top surface 2181C2 relative to the bottom surface 218B. In some embodiments, as illustrated in FIG. 4B, an included angle A3 between the sidewall 212S of the dielectric layer 212 and the concave top surface 2181C2 of the first portion 2181 of the glue layer 218 is less than the included angle A1 as shown in FIG. 2G. For example, the included angle A3 ranges from about 30 degrees to less than about 90 degrees.

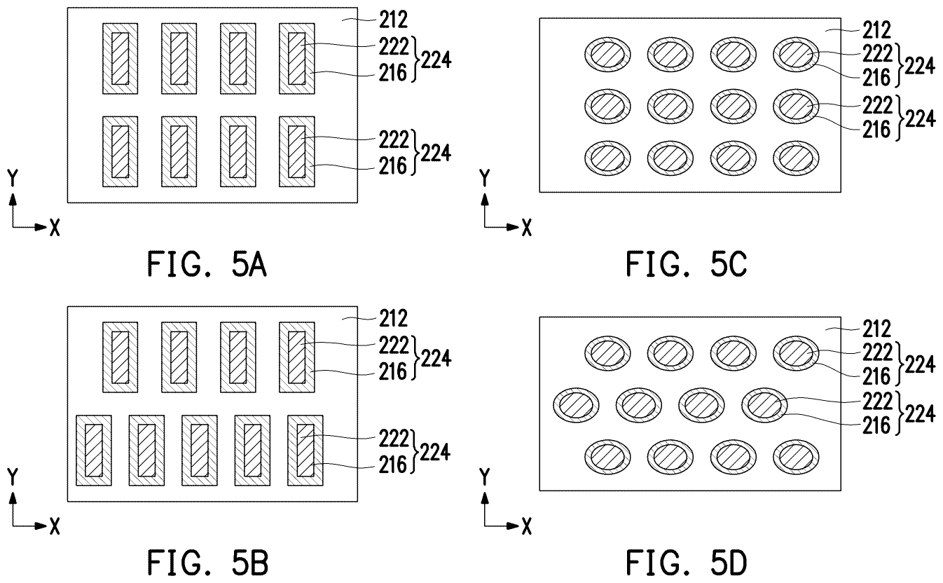

FIG. 5A to FIG. 5D are schematic top views of exemplary arrays after formation of electrodes of transistor structures in accordance with some embodiments of the present disclosure. Except for the further description, the definition of the reference symbols and labeled representations are the same as FIG. 2A to FIG. 4B, and will not be repeated herein.

Referring to FIG. 5A, an array of electrode units 224 is disposed within the dielectric layer 212. A shape of each electrode unit 224 is defined by the opening O2 as the above description. Each electrode unit 224 includes the electrode 222, and the liner layer 216 enclosing the electrodes 222. The electrode 222 and the liner layer 216 are revealed from the dielectric layer 212. The electrode 222 may have a rectangle shape. The liner layer 216 may have a rectangle ring shape enclosing the electrode 222. The electrode units 224 are laterally spaced from each other. In some embodiments, a first row and a second row of the electrode units are parallel in a Y-direction and are aligned with each other in a X-direction. The electrode units 224 may be arranged in more than two rows and more than four columns, the number of the electrode units 224 is not limited thereto. In some embodiments, a minimum distance of an adjacent electrodes 222 along a X-direction/or a Y-direction ranges from greater than about 0 to about less than 200 nm. In some embodiments, a width along the X-direction of the electrode 222 ranges from greater than about 0 to about less than 200 nm. In some embodiments, a length along the Y-direction of the electrode 222 ranges from greater than about 0 to about less than 200 nm.

Referring to FIG. 5B, except for the further description, the definition of the reference symbols and labeled representations are the same as FIG. 5A, and will not be repeated herein. In some embodiments, a first row and a second row of the electrode units are parallel in a Y-direction. The first row of the electrodes 222 and the second row of electrodes 222 are in a staggered arrangement in a X-direction.

Referring to FIG. 5C, except for the further description, the definition of the reference symbols and labeled representations are the same as FIG. 5A, and will not be repeated herein.

The electrode 222 may have an oval shape or a circle shape. The liner layer 216 may have a ring shape enclosing the electrode 222. The electrode units 224 are laterally spaced from each other. In some embodiments, a first row, a second row and a third row of the electrode units are parallel to each other in a Y-direction, and are aligned with each other in a X-direction. In some embodiments, a minimum distance of an adjacent electrodes 222 along a X-direction/or a Y-direction ranges from greater than about 0 to about less than 200 nm. In some embodiments, a first diameter along the X-direction of the electrode 222 ranges from greater than about 0 to about less than 200 nm. In some embodiments, a second diameter along the Y-direction of the electrode 222 ranges from greater than about 0 to about less than 200 nm.

Referring to FIG. 5D, except for the further description, the definition of the reference symbols and labeled representations are the same as FIG. 5C, and will not be repeated herein. In some embodiments, a first row, a second row and third row of the electrode units are parallel to each other in a Y-direction. The first row, the second row and the third row of the electrodes are in a staggered arrangement with an adjacent row in a X-direction. In FIG. 5A to FIG. 5D, only some schematic top views of the exemplary arrays are shown for simplicity, but the disclosure is not limited thereto.

A transistor structure and a method of forming the same are provided. A transistor structure has an electrode (e.g. a source/drain electrode) disposed in a dielectric layer, disposed on a channel layer, and surrounded by a liner layer. The electrode covers a bottom surface of the liner layer, covers the whole revealed surface of the channel layer exposed from the dielectric layer, and is in contact with sidewalls of the dielectric layer. The liner layer is spaced apart from the channel layer by the electrode. Accordingly, the transistor structure has a lower resistance since the current directly goes from the electrode to the channel layer without the reduction of the current (Iₒₙ) caused by the issue that the liner layer with a higher resistivity is in contact with the channel layer. Also, the stability, the performance, and the lifetime of the transistor structure are improved since the liner layer surrounding sidewalls of the electrode prevents the transistor structure from the damage of the subsequent processes. The damage may be caused by the invasion of the elements such as hydrogen atom (H) or other defect elements coming from the subsequent processes such as the silicon oxide deposition, the gas treatment, the plasma bombard or the like. The formation of the electrode and the liner layer are formed by the method including deposition/and removal processes of a sacrificial layer rather than using a plasma process such as the plasma bombard that would damage the quality of the transistor structure. Therefore, the reliability and the performance of the transistor structure are improved.

In accordance with some embodiments of the disclosure, a transistor structure is provided. The transistor structure includes a gate electrode disposed in a dielectric layer of an interconnect structure, a high-k dielectric layer disposed on the gate electrode, a channel layer disposed on the high-k dielectric layer, an electrode disposed on and in contact with the channel layer, and a liner layer surrounding sidewalls of the electrode. The liner layer is spaced apart from the channel layer by the electrode. The liner layer has a resistivity higher than the electrode. The electrode includes a glue layer disposed on and in contact with the channel layer, and a metallic portion surrounded by the glue layer.

In accordance with some embodiments of the disclosure, a transistor structure is provided. The transistor structure includes a gate electrode disposed in an interconnect structure above a substrate, a channel layer disposed on the gate electrode, a high-k dielectric layer is sandwiched between the gate electrode and the channel layer, an electrode disposed on and in contact with the channel layer, and a liner layer surrounding sidewalls of the electrode. The electrode is surrounded by a dielectric layer. The liner layer is sandwiched between the electrode and the dielectric layer, and has a resistivity higher than the electrode. The electrode includes a glue layer and a metallic portion disposed on and surrounded by the glue layer. The glue layer is on the channel layer, covers a bottom surface of the liner layer, and is in contact with the dielectric layer.

In accordance with some embodiments of the disclosure, a method of forming a transistor structure is provided. A gate electrode is formed in a first dielectric layer of an interconnect structure. A high-k dielectric layer is deposited on the gate electrode. A channel layer is deposited on the high-k dielectric layer. A second dielectric layer is deposited on the channel layer. The second dielectric layer is etched to form an opening revealing the channel layer. A sacrificial layer is deposited on the channel layer and a portion of sidewalls of the second dielectric layer at a bottom of the opening. A liner layer is deposited on the sidewalls of the second dielectric layer. The liner layer covers a portion of the sacrificial layer. The sacrificial layer is removed to reveal the channel layer and the portion of the sidewalls of the second dielectric layer. A glue layer is deposited on the channel layer, on the portion of the sidewalls of the second dielectric layer, and on the liner layer. The liner layer is spaced apart from the channel layer by the glue layer. A metallic material is filled in the opening. Excess portions of the glue layer and the metallic material are removed to form an electrode. The electrode includes the glue layer and a metallic portion surrounded by the glue layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor structure, comprising:
a gate electrode disposed in a dielectric layer of an interconnect structure;
a high-k dielectric layer disposed on the gate electrode;
a channel layer disposed on the high-k dielectric layer;
an electrode disposed on and in contact with the channel layer;
a liner layer surrounding sidewalls of the electrode, and spaced apart from the channel layer by the electrode, wherein the liner layer has a resistivity higher than the electrode,
wherein the electrode comprises:
a glue layer disposed on and in contact with the channel layer; and
a metallic portion surrounded by the glue layer.

2. The transistor structure of claim 1, wherein the electrode is a source/drain electrode, the liner layer is spaced apart from the channel layer by the glue layer of the electrode.

3. The transistor structure of claim 1, wherein the electrode is disposed in a second dielectric layer which is on the channel layer, and the glue layer of the electrode comprises:
a first portion extending on a top surface of the channel layer, extending below a bottom surface of the liner layer, and in contact with sidewalls of the second dielectric layer; and
a second portion extending from the first portion and surrounding sidewalls of the metallic portion.

4. The transistor structure of claim 3, wherein the first portion of the glue layer is sandwiched between the top surface of the channel layer and the bottom surface of the liner layer, and between the top surface of the channel layer and the metallic portion.

5. The transistor structure of claim 3, wherein the second portion of the glue layer is sandwiched between the sidewalls of the metallic portion and sidewalls of the liner layer.

6. The transistor structure of claim 3, wherein the first portion has a convex surface protruding out of the first portion and in contact with the bottom surface of the liner layer, and wherein the bottom surface of the liner layer is a concave surface.

7. The transistor structure of claim 3, wherein the first portion has a concave surface concave into the first portion and in contact with the bottom surface of the liner layer, and wherein the bottom surface of the liner layer is a convex surface.

8. A transistor structure, comprising:
a gate electrode disposed in an interconnect structure above a substrate;
a channel layer disposed on the gate electrode;
a high-k dielectric layer is sandwiched between the gate electrode and the channel layer;
an electrode disposed on and in contact with the channel layer, and surrounded by a dielectric layer;
a liner layer surrounding sidewalls of the electrode and sandwiched between the electrode and the dielectric layer, wherein the liner layer has a resistivity higher than the electrode,
wherein the electrode comprises:
a glue layer on the channel layer, covering a bottom surface of the liner layer, and in contact with the dielectric layer; and
a metallic portion disposed on and surrounded by the glue layer.

9. The transistor structure of claim 8, wherein the electrode is a source/drain electrode, and the liner layer is spaced apart from the channel layer by the glue layer of the electrode.

10. The transistor structure of claim 8, wherein the glue layer of the electrode comprises:
a first portion extending on a top surface of the channel layer, extending below the bottom surface of the liner layer, and in contact with sidewalls of the dielectric layer; and
a second portion extending from the first portion and surrounding sidewalls of the metallic portion.

11. The transistor structure of claim 10, wherein the first portion of the glue layer is sandwiched between the top surface of the channel layer and the bottom surface of the liner layer, and between the top surface of the channel layer and the metallic portion.

12. The transistor structure of claim 10, wherein the second portion of the glue layer is sandwiched between the sidewalls of the metallic portion and sidewalls of the liner layer.

13. The transistor structure of claim 10, wherein the first portion has a convex surface protruding out of the first portion and in contact with the bottom surface of the liner layer, and wherein the bottom surface of the liner layer is a concave surface.

14. The transistor structure of claim 10, wherein the first portion has a concave surface concave into the first portion and in contact with the bottom surface of the liner layer, and wherein the bottom surface of the liner layer is a convex surface.

15. A method of forming a transistor structure, comprising:
forming a gate electrode disposed in a first dielectric layer of an interconnect structure;
depositing a high-k dielectric layer on the gate electrode;
depositing a channel layer on the high-k dielectric layer;
depositing a second dielectric layer on the channel layer;
etching the second dielectric layer to form an opening revealing the channel layer;
depositing a sacrificial layer on the channel layer and a portion of sidewalls of the second dielectric layer at a bottom of the opening;
depositing a liner layer on the sidewalls of the second dielectric layer, wherein the liner layer covers a portion of the sacrificial layer;
removing the sacrificial layer to reveal the channel layer and the portion of the sidewalls of the second dielectric layer;
depositing a glue layer on the channel layer, on the portion of the sidewalls of the second dielectric layer, and on the liner layer, wherein the liner layer is spaced apart from the channel layer by the glue layer;
filling a metallic material in the opening; and
removing excess portions of the glue layer and the metallic material to form an electrode comprising the glue layer and a metallic portion surrounded by the glue layer.

16. The method of claim 15,
wherein the electrode is a source/drain electrode,
wherein the glue layer is sandwiched between a top surface of the channel layer and a bottom surface of the liner layer, and between the top surface of the channel layer and the metallic portion, and
wherein the glue layer is in contact with the second dielectric layer.

17. The method of claim 15, wherein removing the sacrificial layer comprises performing a wet etching process or a thermal process.

18. The method of claim 15, wherein depositing the sacrificial layer comprises selectively depositing the sacrificial layer on the channel layer.

19. The method of claim 16, wherein the sacrificial layer has a convex surface in contact with the bottom surface of the liner layer, thereby the glue layer is formed with a convex surface in contact with the bottom surface of the liner layer after the sacrificial layer is removed.

20. The method of claim 16, wherein the sacrificial layer has a concave surface in contact with the bottom surface of the liner layer, thereby the glue layer is formed with a concave surface in contact with the bottom surface of the liner layer after the sacrificial layer is removed.
